(19) United States
(12) Patent Application Publication
(10) Pub. No.: US 2024/0331617 A1
(43) Pub. Date: Oct. 3, 2024

(54) DISPLAY PANEL AND MANUFACTURING METHOD THEREOF

(71) Applicant: GUANGZHOU CHINA STAR OPTOELECTRONICS SEMICONDUCTOR DISPLAY TECHNOLOGY CO., LTD., Guangzhou (CN)

(72) Inventor: Wei Wu, Guangzhou (CN)

(21) Appl. No.: 18/523,400

(22) Filed: Nov. 29, 2023

(30) Foreign Application Priority Data
Mar. 31, 2023 (CN) 202310341105.2

(51) Int. Cl. G09G 3/32; G09G 3/00; H01L 25/075; H01L 33/62

(52) U.S. Cl. CPC G09G 3/32; G09G 3/006; H01L 25/0753; H01L 33/62; G09G 2300/0842; G09G 2330/12; H01L 2933/0066

(57) ABSTRACT

Provided are a display panel and a manufacturing method thereof. The display panel includes: a plurality of light-emitting diodes disposed on a substrate; a first electrode wiring disposed on the substrate; a plurality of pixel driving circuits disposed on the substrate pixel driving circuit; and a detection pad portion. The detection pad is disposed at a non-edge portion of the substrate.

### CROSS-REFERENCE TO RELATED APPLICATION

This application claims priority to Chinese Patent Application No. 202310341105.2, filed on Mar. 31, 2023, the disclosure of which is incorporated herein by reference in its entirety.

### TECHNICAL FIELD

The present disclosure relates to the field of display technologies, and in particular, to a display panel and a manufacturing method thereof.

### BACKGROUND

With development of display technologies, display panels, such as display screens of mobile phones, computers and televisions, have been widely used in people's lives. Miniature light-emitting diode (such as, Min-LED, or Micro-LED) display panels have been developed. During manufacturing the miniature light-emitting diode, multiple processes are performed, and each of the multiple processes has a certain yield. In order to prevent defective products from flowing to latter process and wasting the production capacity, materials, and labor costs of the latter process, it is necessary to conduct certain tests after each process. Lighting process for the miniature light-emitting diodes after the miniature light-emitting diodes being transferred to a backplane or array substrate is one of the important inspection processes. In order to realize the lighting process, cell test signal lines and pads need to be placed on a driving backplane of a display panel, that is, same signals of all pixels are connected together, and signals from the outside are connected through the pads, to realize the overall lighting of the whole display panel. However, the cell test signal lines and the pads affect a bezel of the miniature light-emitting diode display panel, so it is generally necessary to cut off the pads after the lighting process to achieve a narrow bezel.

However, during the working process of the miniature light-emitting diode display panel, there is a problem that water vapor in the environment penetrates into the miniature light-emitting diode display panel through a wiring or an electrode exposed at an edge of the substrate (side surfaces of the substrate).

### SUMMARY

Embodiments of the present disclosure provide a display panel and a manufacturing method thereof, which can solve the problem that water vapor in the environment penetrates into the miniature light-emitting diode display panels through wirings or electrodes exposed at edges of substrates during the working process of the miniature light-emitting diode display panels.

An embodiment of the present disclosure provides a display panel, which includes: a substrate; a plurality of light-emitting diodes disposed on the substrate, wherein each of the plurality of light-emitting diodes includes a first electrode and a second electrode; a first electrode wiring disposed on the substrate and electrically connected to second electrodes of the plurality of light-emitting diodes; a plurality of pixel driving circuits disposed on the substrate, wherein each of the plurality of pixel driving circuits includes a driving sub-circuit and a detection sub-circuit; the driving sub-circuit is at least coupled to the first electrode of a corresponding one of the plurality of light-emitting diodes; the detection sub-circuit includes a detection input terminal and a detection output terminal; and the detection sub-circuit is coupled to the first electrode of the corresponding one of the plurality of light-emitting diodes through the detection output terminal; and a detection pad portion, wherein the detection pad portion includes a first detection pad and a second detection pad, the first detection pad is electrically connected to detection input terminals of detection sub-circuits of the plurality of pixel driving circuits, and the second detection pad is electrically connected to the first electrode wiring; wherein the detection pad portion is disposed at a non-edge portion of the substrate.

In some embodiments of the present disclosure, the detection sub-circuit further includes a detection driving terminal, and the detection driving terminal of the detection sub-circuit is electrically connected to the detection input terminal.

In some embodiments of the present disclosure, detection sub-circuit further includes a detection driving terminal; and the detection pad portion further includes a third detection pad, and the third detection pad is electrically connected to detection driving terminals of detection sub-circuits of the plurality of pixel driving circuits.

In some embodiments of the present disclosure, the detection sub-circuit includes a detection transistor, and a source electrode, a drain electrode and a gate electrode of the detection transistor are the detection input terminal, the detection output terminal and the detection driving terminal, respectively.

In some embodiments of the present disclosure, the display panel further includes a plurality of first detection wirings, and the plurality of first detection wirings are configured to electrically connect first electrodes of the plurality of light-emitting diodes to the first detection pad.

In some embodiments of the present disclosure, the display panel further includes a display area and a non-display area, and the detection pad portion is disposed in the display area.

In some embodiments of the present disclosure, the driving sub-circuit includes a driving transistor, a switching transistor, and a storage capacitor; and wherein an output terminal of the switching transistor is electrically connected to a driving terminal of the driving transistor and a first capacitor electrode plate of the storage capacitor, and an output terminal of the driving transistor is electrically connected to the first electrode of the corresponding one of the plurality of light-emitting diodes and a second capacitor electrode plate of the storage capacitor.

In some embodiments of the present disclosure, the driving sub-circuit further includes a monitoring transistor, an output terminal of the monitoring transistor is electrically connected to the first electrode of the corresponding one of the plurality of light-emitting diodes, the output terminal of the driving transistor and the second capacitor electrode plate of the storage capacitor.

Accordingly, an embodiment of the present disclosure provides a manufacturing method of display panel, and the method includes: providing a motherboard to be tested, wherein the motherboard to be tested includes a plurality of display panels, and each of the plurality of display panels is the display panel is any one display panel described above; providing a detection power supply, wherein the detection power supply includes a plurality of electric signal output terminals; electrically connecting the plurality of electrical signal output terminals of the detection power supply to corresponding detection pads of the detection pad portion; turning on the detection power supply, and lighting the plurality of light-emitting diodes in the display panel, to detect whether all of the plurality of light-emitting diodes in the display panel are normally lighted; and cutting the motherboard to be tested to form the plurality of display panels, wherein the detection pad portion is disposed at the non-edge portion of the substrate.

In some embodiments of the present disclosure, the detect whether all of the light-emitting diodes in the display panel are normally lighted, includes: in response to determine a light-emitting diode being damaged, repairing the damaged light-emitting diode.

The embodiments of the present disclosure provide a display panel and a manufacturing method thereof. The display panel includes: a substrate; a plurality of light-emitting diodes disposed on the substrate, wherein each of the plurality of light-emitting diodes includes a first electrode and a second electrode; a first electrode wiring disposed on the substrate and electrically connected to second electrodes of the plurality of light-emitting diodes; a plurality of pixel driving circuits disposed on the substrate, wherein each of the plurality of pixel driving circuits includes a driving sub-circuit and a detection sub-circuit; the driving sub-circuit is at least coupled to the first electrode of a corresponding one of the plurality of light-emitting diodes; the detection sub-circuit includes a detection input terminal and a detection output terminal; and the detection sub-circuit is coupled to the first electrode of the corresponding one of the plurality of light-emitting diodes through the detection output terminal; and a detection pad portion, wherein the detection pad portion includes a first detection pad and a second detection pad, the first detection pad is electrically connected to detection input terminals of detection sub-circuits of the plurality of pixel driving circuits, and the second detection pad is electrically connected to the first electrode wiring; wherein the detection pad portion is disposed at a non-edge portion of the substrate. In the present disclosure, the detection sub-circuit is included in the pixel driving circuit, the detection sub-circuit is coupled to the first electrode of the corresponding light-emitting diode through the detection output terminal of the detection sub-circuit, the first detection pad is electrically connected to the detection input terminals of the detection sub-circuits, and the second detection pad is electrically connected to the first electrode wiring. As such, whether the light-emitting diodes are damaged can be detected by detecting an input signal of the detection pad portion, and at the same time, when detection of the light-emitting diodes is not needed, the detection sub-circuit can be turned off to avoid the influence of the detection pad portion and electrode wrings on the light-emitting diode. The detection pad portion is not disposed at the edge of the substrate, therefore, the detection pad portion does not need to be cut off in during manufacturing the display panel, and wirings or electrodes can be prevented from being exposed at the edge of the substrate, so that water vapor in the environment can be prevented from penetrating into the miniature light-emitting diode display panel through wirings or electrodes exposed at the edge of the substrate, and the reliability of the display panel is improved.

### BRIEF DESCRIPTION OF THE DRAWINGS

In order to explain the technical solutions in the embodiments of the present disclosure more clearly, accompanying drawings in the description of the embodiments are briefly described hereinafter. Apparently, the accompanying drawings in the following description are merely some embodiments of the present disclosure, and other drawings can be obtained by those skilled in the art according to these drawings without creative work.

FIG. 1 illustrates a schematic top diagram of a part of a display panel provided in an embodiment 1 of the present disclosure.

FIG. 2 illustrates a schematic enlarged diagram of a sub-pixel 10 in FIG. 1.

FIG. 3 illustrates a schematic top diagram of a part of a display panel provided in an embodiment 2 of the present disclosure.

FIG. 4 illustrates a schematic enlarged diagram of a sub-pixel 10 in FIG. 3.

FIG. 5 illustrates a flow block of a manufacturing method of display panel provided in an embodiment 3 of the present disclosure.

### DETAILED DESCRIPTION OF THE EMBODIMENTS

Technical solutions in the embodiments of the present disclosure will be clearly and completely described with reference to the accompanying drawings in the embodiments of the present disclosure. Apparently, the described embodiments are merely parts of embodiments of the present disclosure, but not all the embodiments. Based on the described embodiments in the present disclosure, all other embodiments obtained by those skilled in the art without creative work fall in the scope of protection of the present disclosure. Furthermore, it should be understood that the specific embodiments described herein are merely used to illustrate and explain the present disclosure, and are not intended to limit the present disclosure. In the present disclosure, unless otherwise stated, directional words such as “upper” and “lower” usually refer to the upper and lower of a device in an actual use or working state, which are specifically referring to drawing directions in the drawings; and directional words such as “inside” and “outside” are represented with respect to an outline of the device.

An embodiment of the present disclosure provides a display panel, the display panel includes: a substrate; a plurality of light-emitting diodes disposed on a substrate, wherein each of the plurality of light-emitting diodes includes a first electrode and a second electrode; a first electrode wiring disposed on the substrate and electrically connected to the second electrodes of the plurality of light-emitting diodes; a plurality of pixel driving circuits disposed on the substrate, wherein each of the plurality of pixel driving circuits includes a driving sub-circuit and a detection sub-circuit, the driving sub-circuit is at least coupled to the first electrode of a corresponding one of the plurality of light-emitting diodes, the detection sub-circuit includes a detection input terminal and a detection output terminal, the detection sub-circuit is coupled to the first electrode of a corresponding one of the plurality of light-emitting diodes through the detection output terminal; and a detection pad portion, wherein the detection pad portion includes a first detection pad and a second detection pad, the first detection pad is electrically connected to the detection input terminals of the detection sub-circuits, and the second detection pad is electrically connected to the first electrode wiring. The detection pad is disposed at a non-edge portion of the substrate. The following are described in detail. It should be noted that a description order of the following embodiments is not taken as a limitation to the preferred order of the embodiments.

### Embodiment 1

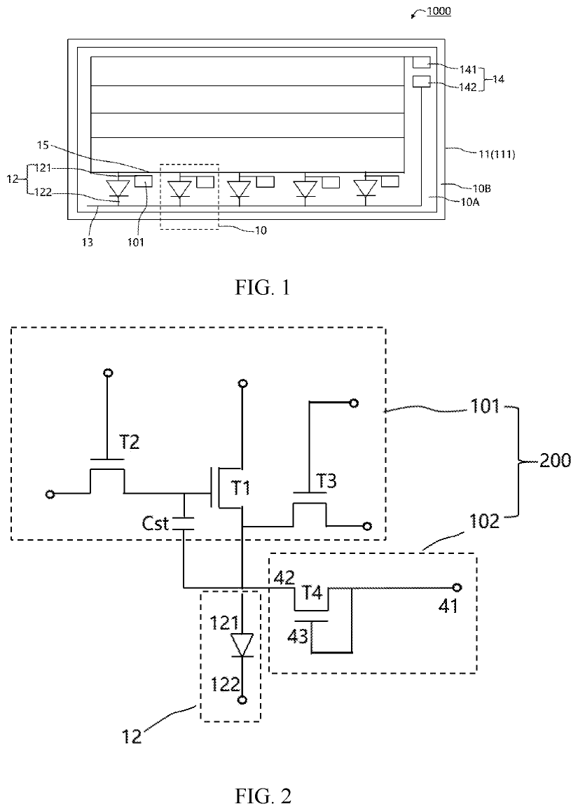

Referring to FIG. 1 and FIG. 2, FIG. 1 illustrates a schematic top diagram of a part of a display panel provided in the embodiment 1 of the present disclosure, and FIG. 2 illustrates a schematic enlarged diagram of a sub-pixel 10 in FIG. 1.

The embodiment of the present disclosure provides a display panel 1000, which includes a substrate 11, a plurality of light-emitting diodes 12, a first electrode wiring 13, a plurality of pixel driving circuits 200, and a detection pad portion 14. The plurality of light-emitting diodes 12 are disposed on the substrate 11, and each of the plurality of light-emitting diodes 12 includes a first electrode 121 and a second electrode 122. The first electrode wiring 13 is disposed on the substrate 11, and the first electrode wiring 13 is electrically connected to the second electrodes 122 of the plurality of light-emitting diodes 12. The plurality of pixel driving circuits 200 are disposed on the substrate 11, and each of the plurality of pixel driving circuits 200 includes a driving sub-circuit 101 and a detection sub-circuit 102. The driving sub-circuit 101 is at least coupled to a first electrode 121 of a corresponding one of the plurality of light-emitting diodes 12. The detection sub-circuit 102 includes a detection input terminal 41 and a detection output terminal 42, and the detection sub-circuit 102 is coupled to a first electrode 121 of a corresponding one of the plurality of light-emitting diodes 12 through the detection output terminal 42. The detection pad portion 14 includes a first detection pad 141 and a second detection pad 142. The first detection pad 141 is electrically connected to the detection input terminals 41 of the detection sub-circuits 102, and the second detection pad 142 is electrically connected to the first electrode wiring 13. The detection pad portion 14 is disposed at a non-edge portion of the substrate 11.

In an embodiment, the substrate 11 may be a glass substrate, but it is not limited thereto.

In an embodiment, the display panel 1000 includes the plurality of light-emitting diodes 12 disposed on the substrate 11. The plurality of light-emitting diodes 12 can be used as a light source of a backlight of the display panel, and the plurality of light-emitting diodes 12 can also be used as parts of sub-pixels of the display panel that directly display images.

In an embodiment, each of the plurality of light-emitting diodes 12 includes the first electrode 121 and the second electrode 122. The first electrode 121 can be a positive electrode or an anode of the light-emitting diode 12, and the second electrode 122 can be a negative electrode or a cathode of the light-emitting diode 12.

It should be understood that one sub-pixel may include one pixel driving circuit 200 and one light-emitting diode 12, and the one pixel driving circuit 200 corresponds to the one light-emitting diode 12.

In an embodiment, each of the plurality of pixel driving circuits 200 includes the driving sub-circuit 101 and the detection sub-circuit 102. The driving sub-circuit 101 drives the corresponding light-emitting diode 12 to emit lights when the display panel 1000 works normally. The detection sub-circuit 102 drives the corresponding light-emitting diode 12 to emit lights when detecting whether the corresponding light-emitting diode 12 in the display panel 1000 emits light normally or is damaged, and the detection sub-circuit 102 does not work or does not drive the corresponding light-emitting diode 12 to emit lights when the display panel 1000 works normally.

In an embodiment, the first detection pad 141 is electrically connected to the detection input terminals 41 of the detection sub-circuits 102, and the detection sub-circuit 102 is coupled to the first electrode 121 of a corresponding light-emitting diode 12 through the detection output terminal 42 of the detection sub-circuit 102. That is to say, during detecting the display panel 1000, the first detection pad 141 can provide an electrical signal to the first electrode 121 of the light-emitting diode 12 through the detection output terminals 42.

In an embodiment, the second detection pad 142 is electrically connected to the first electrode wiring 13, and the first electrode wiring 13 are electrically connected to the second electrodes 122 of the plurality of light-emitting diodes 12. That is, during detecting the display panel 1000, the second detection pad 142 provide an electrical signal to the second electrode 122 of the light-emitting diode 12 through the first electrode wiring 13.

In an embodiment, the non-edge portion of the substrate 11 refers to a part outside an edge 111 of the substrate, and it should be understood that the detection pad portion is not exposed from a side surface of the edge 111 of the substrate 11.

In this embodiment, the detection sub-circuit 102 is included in the pixel driving circuit 200, the detection sub-circuit 102 is coupled to the first electrode 121 of the corresponding light-emitting diode 12 through the detection output terminal 42 of the detection sub-circuit 102, the first detection pad 141 is electrically connected to the detection input terminals 41 of the plurality of detection sub-circuits 102, and the second detection pad 142 is electrically connected to the first electrode wiring 13. As such, whether the plurality of light-emitting diodes 12 are damaged can be detected by detecting an input signal of the detection pad portion 14, and at the same time, when the detection is not needed, the detection sub-circuit 102 can be turned off to avoid the influence of the detection pad portion 14 and electrode wrings on the light-emitting diodes 12. Further, the detection pad portion 14 is not disposed at the edge 111 of the substrate 11, therefore, the detection pad portion 14 does not need to be cut off in during manufacturing the display panel, and wirings or electrodes can be prevented from being exposed at the edge 111 of the substrate 11. Thus, water vapor in the environment can be prevented from penetrating into a miniature light-emitting diode display panel through the wirings or electrodes exposed at the edge 111 of the substrate 11, and the reliability of the display panel is improved.

In an embodiment, each detection sub-circuit 102 further includes a detection driving terminal 43, and the detection driving terminal 43 of the detection sub-circuit 102 is electrically connected to the corresponding detection input terminal 41.

In an embodiment, the detection driving terminal 43 of the detection sub-circuit 102 is electrically connected to the corresponding detection input terminal 41. That is, the detection driving terminal 43 of the detection sub-circuit 102 is electrically connected to the detection input terminal 41 of the same detection sub-circuit 102, and the detection driving terminal 43 and the detection input terminal 41 share a wiring or an electrode. As such, the layout of the display panel can be optimized.

In some embodiments, the detection sub-circuit 102 includes a detection transistor T4. A source electrode, a drain electrode, and a gate electrode of the detection transistor T4 are the detection input terminal 41, the detection output terminal 42 and the detection drive terminal 43, respectively.

Specifically, the detection transistor T4 is included in the detection sub-circuit 102, which makes the detection sub-circuit 102 simple in structure and can optimize the layout of the display panel.

In some embodiments, the display panel 1000 includes a display area 10A and a non-display area 10B, and the detection pad portion 14 is disposed in the display area 10A.

Specifically, the non-display area 10B is at least partially disposed around the display area 10A, and the detection pad portion 14 is disposed in the display area 10A, so that the detection pad portion 14 is disposed away from the edge 111 of the substrate 11.

Further, the display panel 1000 can also include an encapsulation layer, and the encapsulation layer seals the display area 10A, thus better preventing wirings or electrodes from being exposed outside, preventing water vapor in the environment from penetrating into the miniature light-emitting diode display panel through the exposed wiring or electrodes at the edge 111 of the substrate 11, and improving the reliability of the display panel.

In some embodiments, the display panel 1000 further includes a plurality of first detection wirings 15, and the first detection wirings 15 are configured to electrically connect the first electrodes 121 of the plurality of light-emitting diodes 12 to the first detection pad 141.

Specifically, the plurality of first detection wirings 15 are disposed in the display panel to electrically connect the first electrodes 121 of the plurality of light-emitting diodes 12 to the first detection pad 141.

In some embodiments, the driving sub-circuit 101 includes a driving transistor T1, a switching transistor T2, and a storage capacitor Cst. An output terminal of the switching transistor T2 is electrically connected to a driving terminal of the driving transistor T1 and a first capacitor electrode plate of the storage capacitor Cst, and an output terminal of the driving transistor T1 is electrically connected to the first electrode 121 of the corresponding light-emitting diode 12 and a second capacitor electrode plate of the storage capacitor Cst.

In some embodiments, the driving sub-circuit further includes a monitoring transistor T3. An output terminal of the monitoring transistor T3 is electrically connected to the first electrode 121 of the corresponding light-emitting diode 12, the output terminal of the driving transistor T1 and the second capacitor electrode plate of the storage capacitor Cst.

Specifically, the output terminals of the driving transistor T1, the switching transistor T2 and the monitoring transistor T3 refer to drain electrodes of the driving transistor T1, the switching transistor T2 and the monitoring transistor T3, respectively. The driving terminals of the driving transistor T1, the switching transistor T2 and the monitoring transistor T3 refer to gate electrodes of the driving transistor T1, the switching transistor T2 and the monitoring transistor T3, respectively. The input terminals of the driving transistor T1, the switching transistor T2 and the monitoring transistor T3 refer to source electrodes of the driving transistor T1, the switching transistor T2 and the monitoring transistor T3, respectively.

### Embodiment 2

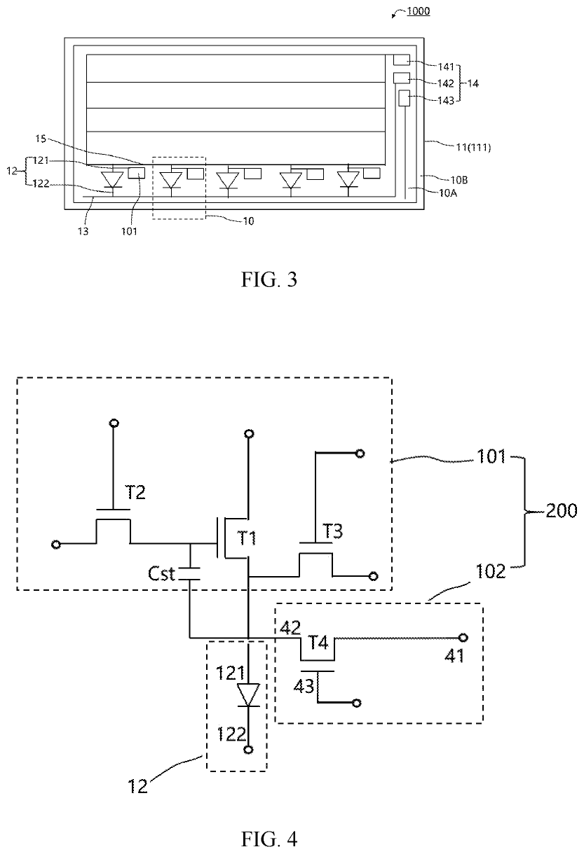

Referring to FIG. 3 and FIG. 4, FIG. 3 illustrates a schematic top diagram of a part of a display panel provided in the embodiment 2 of the present disclosure, and FIG. 4 illustrates a schematic enlarged diagram of a sub-pixel 10 in FIG. 3.

The display panel in this embodiment is the same as or similar to any one display panel 1000 described in the embodiment 1, and the similarities are not repeated here, only the differences are described herein.

In some embodiments, the detection sub-circuit 102 further includes a detection driving terminal 43, the detection pad portion 14 further includes a third detection pad 143, and the third detection pad 143 is electrically connected to the detection driving terminal 43 of the detection sub-circuit.

Specifically, in this embodiment, compared with the embodiment 1, the third detection pad 143 supplies an electric signal separately through the detection driving terminal 43, which can improve the control flexibility of the display panel or the detection sub-circuit 102.

### Embodiment 3

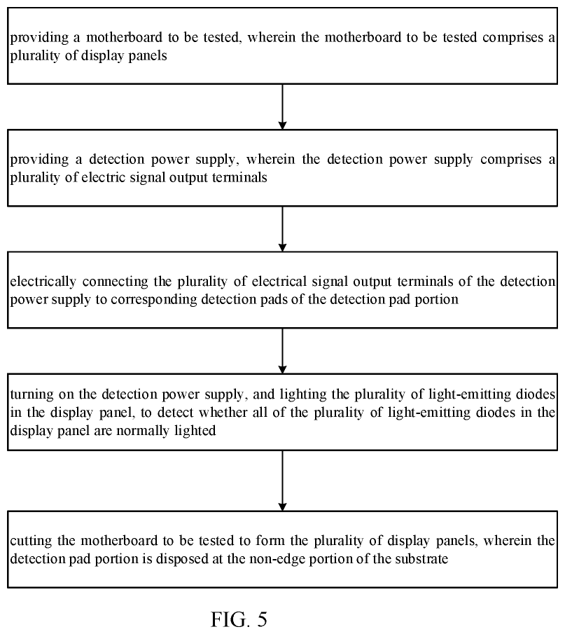

Referring to FIG. 5, FIG. 5 illustrates a flow block of a manufacturing method of display panel provided in an embodiment 3 of the present disclosure.

The display panel 1000 in any of the above embodiments can be manufactured by the manufacturing method of display panel in the embodiment 3.

Specifically, the embodiment 3 provides a manufacturing method of display panel, and the method includes steps S100, S200, S300, S400, and S500.

In step S100, a motherboard to be tested is provided, and the motherboard to be tested includes a plurality of display panels described above.

Specifically, during manufacturing the display panel, the motherboard to be tested includes a plurality of display panels of any one of the above embodiments.

In step S200, a detection power supply is provided, and the detection power supply includes a plurality of electrical signal output terminals.

Specifically, the detection power supply is configured to provide the motherboard to be tested with electrical signals to light the plurality of light-emitting diodes 12.

In step S300, the electrical signal output terminals of the detection power supply are electrically connected to corresponding detection pads of the detection pad portions.

Specifically, with respect to the display panel in the embodiment 1, the detection power supply may include a first signal output terminal and a second signal output terminal. The first signal output terminal and the second signal output terminal are electrically connected to the first detection pad 141 and the second detection pad 142, respectively, and supply electrical signals correspondingly. As such, the detection sub-circuit 102 provides an electrical signal to the first electrode and an electrical signal to the second electrode.

Specifically, with respect to the display panel in the embodiment 2, the detection power supply may include a first signal output terminal, a second signal output terminal and a third signal output terminal. The first signal output terminal, the second signal output terminal and the third signal output terminal are electrically connected to the first detection pad terminal 141, the second detection pad terminal 142 and the third detection pad terminal 143, respectively, and supply electrical signals correspondingly. As such, the detection sub-circuit 102 provides an electrical signal to the first electrode and an electrical signal to the second electrode.

In step S400, the detection power supply is turned on, and the light-emitting diodes in the display panel are lighted, to detect whether all the light-emitting diodes in the display panel are normally lighted.

Specifically, the detection power supply is turned on, and the light-emitting diodes 12 in the display panel are lighted. In a case that, a light-emitting diode 12 is abnormally lighted, it means that the abnormally lighted light-emitting diode is damaged and need to be repaired or maintained.

In step S500, the motherboard to be tested is cut to form a plurality of display panels, and the detection pad portion is disposed at non-edge portion of the substrate.

Specifically, the motherboard to be tested is cut to form a plurality of display panels 1000, and the detection pad portion 14 is not disposed at the edge 111 of the substrate 11.

In some embodiments, when detecting whether all the light-emitting diodes in the display panel are normally lighted, a damaged light-emitting diode is needy repaired.

Specifically, in step S400, if the light-emitting diode 12 is damaged, the damaged light-emitting diode is repaired by replacing by another one.

This embodiment has the same beneficial effects as those in the embodiment 1 and embodiment 2, which is not repeated herein.

The display panel and the manufacturing method thereof provided by the embodiments of the present disclosure are described above. The principle and implementation of the present disclosure are explained by using specific embodiments, and the description of the above embodiments is merely intended to help understand the method and core idea of the present disclosure. Moreover, according to the present disclosure, there will be changes in the specific implementation and application scope for those skilled in the art. In summary, the content of this description should not be understood as limitations on the disclosure.

What is claimed is:

1. A display panel, comprising:
a substrate;
a plurality of light-emitting diodes disposed on the substrate, wherein each of the plurality of light-emitting diodes comprises a first electrode and a second electrode;
a first electrode wiring disposed on the substrate and electrically connected to second electrodes of the plurality of light-emitting diodes;
a plurality of pixel driving circuits disposed on the substrate, wherein each of the plurality of pixel driving circuits comprises a driving sub-circuit and a detection sub-circuit; the driving sub-circuit is at least coupled to the first electrode of a corresponding one of the plurality of light-emitting diodes; the detection sub-circuit comprises a detection input terminal and a detection output terminal; and the detection sub-circuit is coupled to the first electrode of the corresponding one of the plurality of light-emitting diodes through the detection output terminal; and
a detection pad portion, wherein the detection pad portion comprises a first detection pad and a second detection pad, the first detection pad is electrically connected to detection input terminals of detection sub-circuits of the plurality of pixel driving circuits, and the second detection pad is electrically connected to the first electrode wiring;
wherein the detection pad portion is disposed at a non-edge portion of the substrate.

2. The display panel of claim 1, wherein the detection sub-circuit further comprises a detection driving terminal, and the detection driving terminal of the detection sub-circuit is electrically connected to the detection input terminal.

3. The display panel of claim 1, wherein the detection sub-circuit further comprises a detection driving terminal; and
the detection pad portion further comprises a third detection pad, and the third detection pad is electrically connected to detection driving terminals of detection sub-circuits of the plurality of pixel driving circuits.

4. The display panel of claim 2, wherein the detection sub-circuit comprises a detection transistor, and a source electrode, a drain electrode and a gate electrode of the detection transistor are the detection input terminal, the detection output terminal and the detection driving terminal, respectively.

5. The display panel of claim 3, wherein the detection sub-circuit comprises a detection transistor, and a source electrode, a drain electrode and a gate electrode of the detection transistor are the detection input terminal, the detection output terminal and the detection driving terminal, respectively.

6. The display panel of claim 4, further comprising a plurality of first detection wirings, and the plurality of first detection wirings are configured to electrically connect first electrodes of the plurality of light-emitting diodes to the first detection pad.

7. The display panel of claim 4, comprising a display area and a non-display area, wherein the detection pad portion is disposed in the display area.

8. The display panel of claim 4, wherein the driving sub-circuit comprises a driving transistor, a switching transistor, and a storage capacitor; and
wherein an output terminal of the switching transistor is electrically connected to a driving terminal of the driving transistor and a first capacitor electrode plate of the storage capacitor, and an output terminal of the driving transistor is electrically connected to the first electrode of the corresponding one of the plurality of light-emitting diodes and a second capacitor electrode plate of the storage capacitor.

9. The display panel of claim 8, wherein the driving sub-circuit further comprises a monitoring transistor, an output terminal of the monitoring transistor is electrically connected to the first electrode of the corresponding one of the plurality of light-emitting diodes, the output terminal of the driving transistor and the second capacitor electrode plate of the storage capacitor.

10. A manufacturing method of display panel, comprising:
providing a motherboard to be tested, wherein the motherboard to be tested comprises a plurality of display panels of claim 1;
providing a detection power supply, wherein the detection power supply comprises a plurality of electric signal output terminals;
electrically connecting the plurality of electrical signal output terminals of the detection power supply to corresponding detection pads of the detection pad portion;
turning on the detection power supply, and lighting the plurality of light-emitting diodes in the display panel, to detect whether all of the plurality of light-emitting diodes in the display panel are normally lighted; and
cutting the motherboard to be tested to form the plurality of display panels, wherein the detection pad portion is disposed at the non-edge portion of the substrate.

11. The manufacturing method of claim 10, wherein the detect whether all of the plurality of light-emitting diodes in the display panel are normally lighted comprises:
in response to determine a light-emitting diode being damaged, repairing the damaged light-emitting diode.

12. The manufacturing method of claim 10, wherein the detection sub-circuit further comprises a detection driving terminal, and the detection driving terminal of the detection sub-circuit is electrically connected to the detection input terminal.

13. The manufacturing method of claim 10, wherein the detection sub-circuit further comprises a detection driving terminal; and
the detection pad portion further comprises a third detection pad, and the third detection pad is electrically connected to detection driving terminals of detection sub-circuits of the plurality of pixel driving circuits.

14. The manufacturing method of claim 12, wherein the detection sub-circuit comprises a detection transistor, and a source electrode, a drain electrode and a gate electrode of the detection transistor are the detection input terminal, the detection output terminal and the detection driving terminal, respectively.

15. The manufacturing method of claim 13, wherein the detection sub-circuit comprises a detection transistor, and a source electrode, a drain electrode and a gate electrode of the detection transistor are the detection input terminal, the detection output terminal and the detection driving terminal, respectively.

16. The manufacturing method of claim 14, further comprising a plurality of first detection wirings, and the plurality of first detection wirings are configured to electrically connect first electrodes of the plurality of light-emitting diodes to the first detection pad.

17. The manufacturing method of claim 14, comprising a display area and a non-display area, wherein the detection pad portion is disposed in the display area.

18. The manufacturing method of claim 14, wherein the driving sub-circuit comprises a driving transistor, a switching transistor, and a storage capacitor; and
wherein an output terminal of the switching transistor is electrically connected to a driving terminal of the driving transistor and a first capacitor electrode plate of the storage capacitor, and an output terminal of the driving transistor is electrically connected to the first electrode of the corresponding one of the plurality of light-emitting diodes and a second capacitor electrode plate of the storage capacitor.

19. The manufacturing method of claim 18, wherein the driving sub-circuit further comprises a monitoring transistor, an output terminal of the monitoring transistor is electrically connected to the first electrode of the corresponding one of the plurality of light-emitting diodes, the output terminal of the driving transistor and the second capacitor electrode plate of the storage capacitor.
